(19) United States
(12) Patent Application Publication
(10) Pub. No.: US 2008/0085015 A1
(43) Pub. Date: Apr. 10, 2008

(54) Economic indoor power amplification system

(76) Inventor: Chen-Lee Chen, Taichung (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/332,650

(22) Filed: Jan. 17, 2006

(51) Int. Cl. H03G 3/00

(52) U.S. Cl. 381/107

(57) ABSTRACT

A power amplification system includes a power supply input interface, a voice source input interface, a plurality of automatic level control circuits, a voice source selection switch, a volume control circuit, a power amplification circuit, an output interface, a microprocessor, an operation device, and an indication device. Thus, the power amplification system has a smaller volume, thereby facilitating storage, packaging and transportation of the power amplification system. In addition, the user only needs to connect the voice sources to the voice source input interface without having to connect external wires, so that the power amplification system is mounted easily and conveniently, thereby facilitating the user mounting the power amplification system. Further, the power amplification system has an inexpensive price, so that the power amplification system satisfies the economic effect.

### BACKGROUND OF THE INVENTION

1. Field of the Invention

The present invention relates to a power amplification system, and more particularly to an economic indoor power amplification system.

2. Description of the Related Art

A conventional power amplifier usually has a determined size whose length and width are the same as that of an external voice source, such as the MP3 player, CD player, CD, MD, tape, DCD, VCR and the like. The power amplifier is connected to a set of loudspeakers, so that the power amplification system including the power amplifier, the external voice source and the loudspeakers occupies a larger space, thereby causing inconvenience in storage, packaging and transportation of the conventional power amplification system. In addition, the conventional power amplification system has an expensive price. Further, the conventional power amplification system has a larger volume, so that it is often installed in the living room or the video place, thereby effecting the privacy of use.

### SUMMARY OF THE INVENTION

In accordance with the preferred embodiment of the present invention, there is provided a power amplification system, comprising a power supply input interface connected to an external adapter, a voice source input interface connected to a plurality of voice sources, a plurality of automatic level control circuits each connected to the voice source input interface and each corresponding to a respective one of the voice sources, a voice source selection switch connected to the automatic level control circuits, a volume control circuit connected to the voice source selection switch, a power amplification circuit connected to the volume control circuit, an output interface connected to the power amplification circuit and connected to a plurality of external loudspeakers, a microprocessor connected to the volume control circuit, an operation device connected to the microprocessor, and an indication device connected to the microprocessor.

In accordance with another preferred embodiment of the present invention, there is provided a power amplification system, comprising a power supply input interface connected to an external adapter, a voice source input interface connected to a plurality of voice sources, a plurality of automatic level control circuits each connected to the voice source input interface and each corresponding to a respective one of the voice sources, a voice source selection circuit connected to the automatic level control circuits, a volume control circuit connected to the voice source selection circuit, a power amplification circuit connected to the volume control circuit, an output interface connected to the power amplification circuit and connected to a plurality of external loudspeakers, a microprocessor connected to the volume control circuit, an operation device connected to the microprocessor, and an indication device connected to the microprocessor.

The primary objective of the present invention is to provide an economic indoor power amplification system.

Another objective of the present invention is to provide a power amplification system that has a smaller volume and occupies a smaller space, thereby greatly facilitating storage, packaging and transportation of the power amplification system.

A further objective of the present invention is to provide a power amplification system, wherein the user only needs to connect the voice sources to the voice source input interface without having to connect external wires, so that the power amplification system is mounted easily and conveniently, thereby facilitating the user mounting the power amplification system.

A further objective of the present invention is to provide a power amplification system that is arranged with an inexpensive price, so that the power amplification system satisfies the economic effect.

A further objective of the present invention is to provide a power amplification system that has a smaller volume so that the power amplification system is arranged in a personal room, thereby keeping the privacy of use.

A further objective of the present invention is to provide a power amplification system that can select input of different voice sources to satisfy the requirements of different users.

Further benefits and advantages of the present invention will become apparent after a careful reading of the detailed description with appropriate reference to the accompanying drawings.

### BRIEF DESCRIPTION OF THE DRAWINGS

FIG. 1 is a block diagram of a power amplification system in accordance with the preferred embodiment of the present invention.

FIG. 2 is a plan view of the power amplification system as shown in FIG. 1.

FIG. 3 is a block diagram of a power amplification system in accordance with another preferred embodiment of the present invention.

FIG. 4 is a block diagram of a power amplification system in accordance with another preferred embodiment of the present invention.

FIG. 5 is a block diagram of a power amplification system in accordance with another preferred embodiment of the present invention.

FIG. 6 is a block diagram of a power amplification system in accordance with another preferred embodiment of the present invention.

FIG. 7 is a plan view of the power amplification system as shown in FIG. 6.

### DETAILED DESCRIPTION OF THE INVENTION

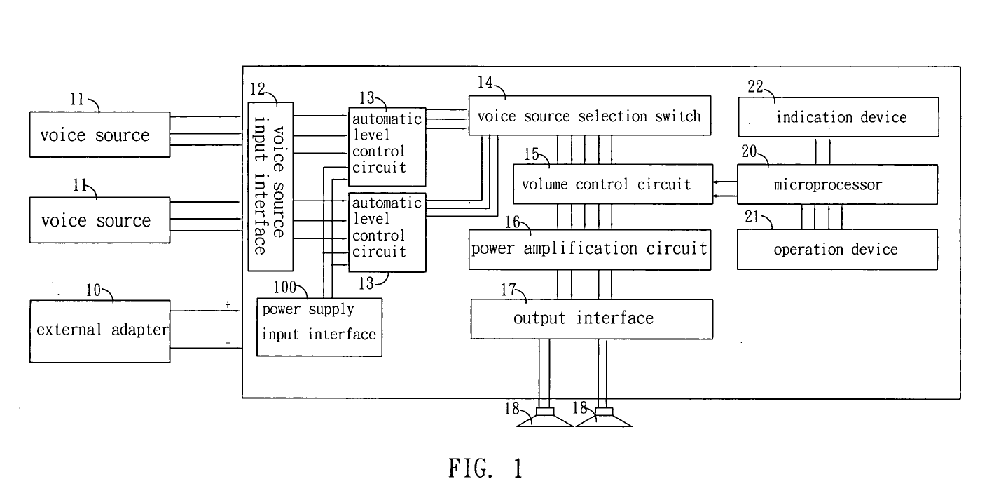

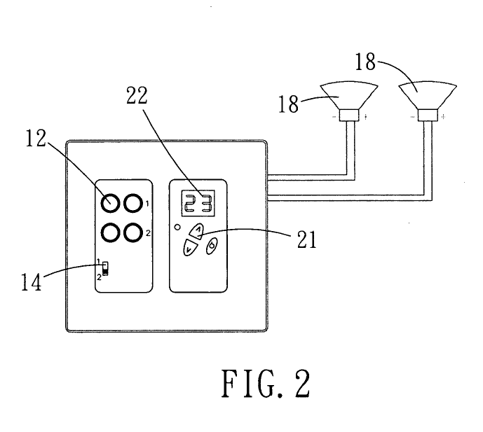

Referring to the drawings and initially to FIGS. 1 and 2, a power amplification system in accordance with the preferred embodiment of the present invention comprises a power supply input interface 100 connected to an external adapter 10 which is connected to an external power supply (not shown), a voice source input interface 12 connected to a plurality of voice sources 11 (such as the MP3 player, CD player, CD, MD, tape, DCD, VCR and the like), a plurality of automatic level control circuits 13 each connected to the voice source input interface 12 and each corresponding to a respective one of the voice sources 11, a voice source selection switch 14 connected to the automatic level control circuits 13, a volume control circuit 15 connected to the voice source selection switch 14, a power amplification circuit 16 connected to the volume control circuit 15, an output interface 17 connected to the power amplification circuit 16 and connected to a plurality of external loudspeakers 18, a microprocessor 20 connected to the volume control circuit 15, an operation device 21 connected to the microprocessor 20, and an indication device 22 connected to the microprocessor 20.

In the preferred embodiment of the present invention, the automatic level control circuits 13 are used to maintain the voice signal output at a constant level automatically, the operation device 21 is a push button that is operable to control the volume, and the indication device 22 is a digital or analogue indicator that is used to indicate the voice source and the volume.

When in use, the voice source selection switch 14 selects the input of different voice sources 11, the operation device 21 adjusts the output of a proper volume by the microprocessor 20, the indication device 22 indicates the voice source and the volume by the microprocessor 20, the automatic level control circuits 13 maintain the selected voice signal output at a constant level automatically, the power amplification circuit 16 amplifies the selected voice signal output, the output interface 17 outputs the amplified voice signal output, and the external loudspeakers 18 sound the amplified voice signal output.

As shown in FIG. 2, the voice source input interface 12, the voice source selection switch 14, the operation device 21, the indication device 22 and the external loudspeakers 18 of the power amplification system are shown.

Accordingly, the power amplification system has a smaller volume and occupies a smaller space, thereby greatly facilitating storage, packaging and transportation of the power amplification system. In addition, the user only needs to connect the voice sources 11 to the voice source input interface 12 without having to connect external wires, so that the power amplification system is mounted easily and conveniently, thereby facilitating the user mounting the power amplification system. Further, the power amplification system is arranged with an inexpensive price, so that the power amplification system satisfies the economic effect. Further, the power amplification system has a smaller volume so that the power amplification system is arranged in a personal room, thereby keeping the privacy of use. Further, the power amplification system can select input of different voice sources to satisfy the requirements of different users.

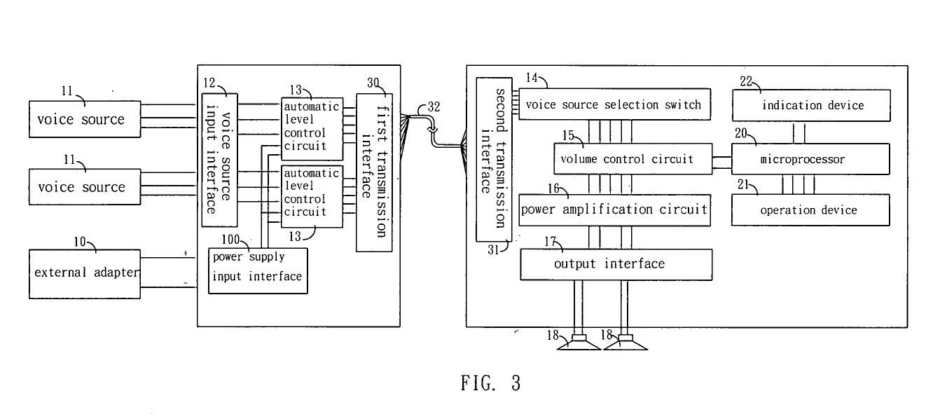

Referring to FIG. 3, the power amplification system further comprises a first transmission interface 30 connected to the automatic level control circuits 13, and a second transmission interface 31 connected to the voice source selection switch 14 and connected to the first transmission interface 30 by wires 32 to connect the voice source selection switch 14 to the automatic level control circuits 13. Thus, the power amplification system is available for places of different sizes.

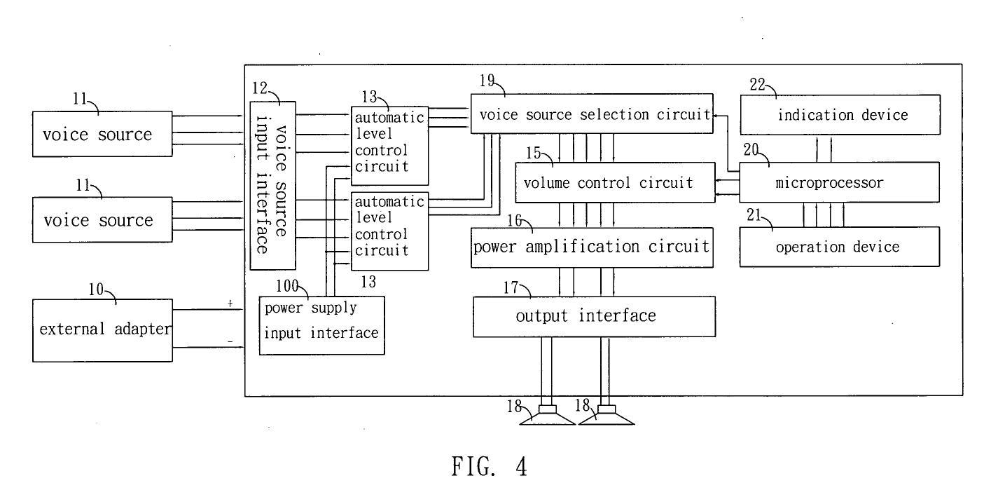

Referring to FIG. 4 with reference to FIG. 1, the voice source selection switch 14 is replaced by a voice source selection circuit 19. In addition, the voice source selection circuit 19 is connected to the microprocessor 20.

When in use, the operation device 21 selects the input of different voice sources 11 by the microprocessor 20 and the voice source selection circuit 19 and adjusts the output of a proper volume by the microprocessor 20 and the volume control circuit 15, the indication device 22 indicates the voice source by the microprocessor 20 and the voice source selection circuit 19 and indicates the volume by the microprocessor 20 and the volume control circuit 15, the automatic level control circuits 13 maintain the selected voice signal output at a constant level automatically, the power amplification circuit 16 amplifies the selected voice signal output, the output interface 17 outputs the amplified voice signal output, and the external loudspeakers 18 sound the amplified voice signal output.

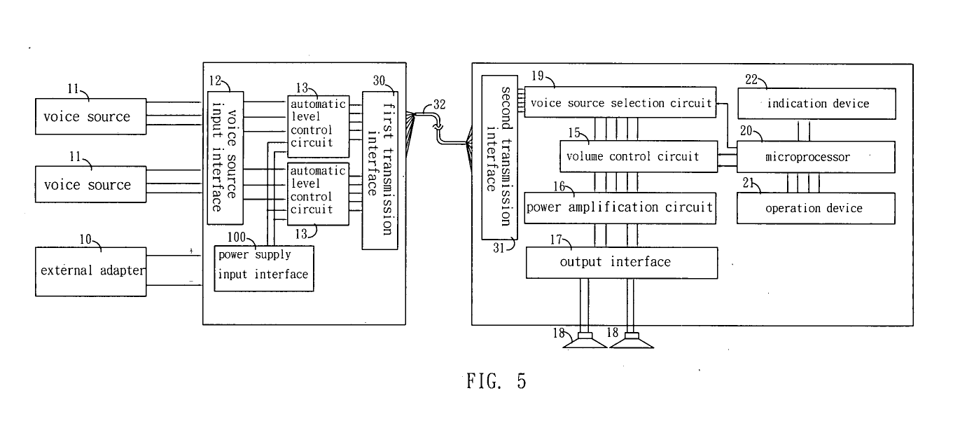

Referring to FIG. 5, the power amplification system further comprises a first transmission interface 30 connected to the automatic level control circuits 13, and a second transmission interface 31 connected to the voice source selection circuit 19 and connected to the first transmission interface 30 by wires 32 to connect the voice source selection circuit 19 to the automatic level control circuits 13. Thus, the power amplification system is available for places of different sizes.

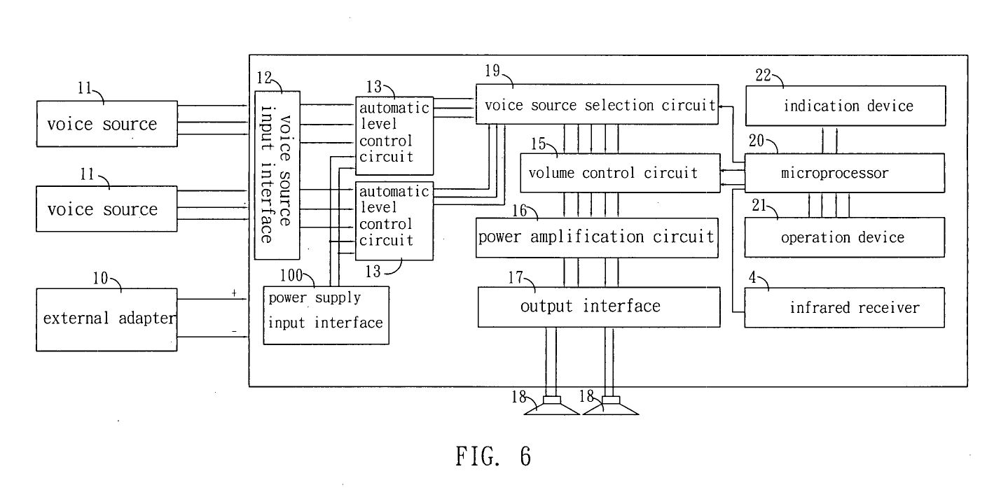

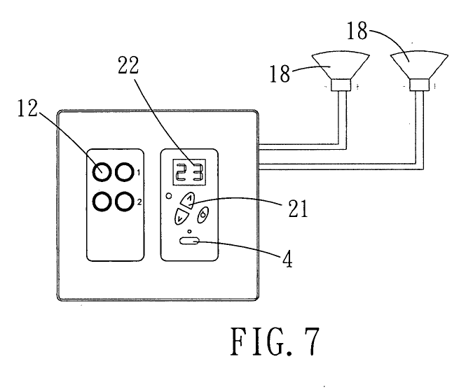

Referring to FIGS. 6 and 7, the power amplification system further comprises an infrared receiver 4 connected to the microprocessor 20 so that the power amplification system is controlled by an infrared remote controller (not shown).

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. A power amplification system, comprising
a power supply input interface connected to an external adapter;
a voice source input interface connected to a plurality of voice sources;
a plurality of automatic level control circuits each connected to the voice source input interface and each corresponding to a respective one of the voice sources;
a voice source selection switch connected to the automatic level control circuits;
a volume control circuit connected to the voice source selection switch;
a power amplification circuit connected to the volume control circuit;
an output interface connected to the power amplification circuit and connected to a plurality of external loudspeakers;
a microprocessor connected to the volume control circuit;
an operation device connected to the microprocessor;
an indication device connected to the microprocessor.

2. The power amplification system in accordance with claim 1, wherein the voice source selection switch selects the input of different voice sources, the operation device adjusts the output of a proper volume by the microprocessor, the indication device indicates the voice source and the volume by the microprocessor, the automatic level control circuits maintain the selected voice signal output at a constant level automatically, the power amplification circuit amplifies the selected voice signal output, the output interface outputs the amplified voice signal output, and the external loudspeakers sound the amplified voice signal output.

3. The power amplification system in accordance with claim 1, wherein the automatic level control circuits are used to maintain the voice signal output at a constant level automatically, the operation device is a push button that is operable to control the volume, and the indication device is a digital or analogue indicator that is used to indicate the voice source and the volume.

4. The power amplification system in accordance with claim 1, further comprising a first transmission interface connected to the automatic level control circuits, and a second transmission interface connected to the voice source selection switch and connected to the first transmission interface by wires to connect the voice source selection switch to the automatic level control circuits.

5. The power amplification system in accordance with claim 1, further comprising an infrared receiver connected to the microprocessor so that the power amplification system is controlled by an infrared remote controller.

6. A power amplification system, comprising
a power supply input interface connected to an external adapter;
a voice source input interface connected to a plurality of voice sources;
a plurality of automatic level control circuits each connected to the voice source input interface and each corresponding to a respective one of the voice sources;
a voice source selection circuit connected to the automatic level control circuits;
a volume control circuit connected to the voice source selection circuit;
a power amplification circuit connected to the volume control circuit;
an output interface connected to the power amplification circuit and connected to a plurality of external loudspeakers;
a microprocessor connected to the volume control circuit;
an operation device connected to the microprocessor;
an indication device connected to the microprocessor.

7. The power amplification system in accordance with claim 6, wherein the voice source selection circuit is connected to the microprocessor.

8. The power amplification system in accordance with claim 6, wherein the operation device selects the input of different voice sources by the microprocessor and the voice source selection circuit and adjusts the output of a proper volume by the microprocessor and the volume control circuit, the indication device indicates the voice source by the microprocessor and the voice source selection circuit and indicates the volume by the microprocessor and the volume control circuit, the automatic level control circuits maintain the selected voice signal output at a constant level automatically, the power amplification circuit amplifies the selected voice signal output, the output interface outputs the amplified voice signal output, and the external loudspeakers sound the amplified voice signal output.

9. The power amplification system in accordance with claim 6, wherein the automatic level control circuits are used to maintain the voice signal output at a constant level automatically, the operation device is a push button that is operable to control the volume, and the indication device is a digital or analogue indicator that is used to indicate the voice source and the volume.

10. The power amplification system in accordance with claim 6, further comprising a first transmission interface connected to the automatic level control circuits, and a second transmission interface connected to the voice source selection circuit and connected to the first transmission interface by wires to connect the voice source selection circuit to the automatic level control circuits.

11. The power amplification system in accordance with claim 6, further comprising an infrared receiver connected to the microprocessor so that the power amplification system is controlled by an infrared remote controller.
